(19) United States
(12) Patent Application Publication
(10) Pub. No.: US 2018/0040505 A1
(43) Pub. Date: Feb. 8, 2018

(54) METHOD FOR FORMING A SHALLOW TRENCH ISOLATION STRUCTURE USING A NITRIDE LINER AND A DIFFUSIONLESS ANNEAL

(71) Applicant: GLOBALFOUNDRIES Inc., Grand Cayman, KY (US)

(72) Inventors: Sandeep Gaan, Clifton Park, NY (US); Shishir Ray, Clifton Park, NY (US); Vikrant Chauhan, Clifton Park, NY (US)

(21) Appl. No.: 15/225,994

(22) Filed: Aug. 2, 2016

(51) Int. Cl. H01L 21/762; H01L 21/324

(52) U.S. Cl. CPC H01L 21/76283; H01L 21/324

(57) ABSTRACT

A method includes forming a trench in a stack comprising a substrate, a buried oxide layer formed above the substrate, a semiconductor layer formed above the buried oxide layer and a hard mask layer formed above the semiconductor layer. A first liner is formed in the trench. A first oxide layer is formed in the trench. A diffusionless anneal process is performed to densify the first oxide layer. The first oxide layer is recessed to define a recess. A second oxide layer is formed in the recess.

### BACKGROUND OF THE INVENTION

### 1. Field of the Invention

The present disclosure generally relates to fully depleted silicon-on-insulator (FDSOI) devices in advanced semiconductor techniques and, more particularly, to preserving strain in a device by forming a shallow trench isolation structure using a nitride liner and a diffusionless anneal process.

### 2. Description of the Related Art

In modern electronic technologies, integrated circuits (ICs) experience a vast applicability in a continuously spreading range of applications. Particularly, the ongoing demand for increasing mobility of electronic devices at high performance and low energy consumption drives developments to more and more compact devices having features with sizes significantly smaller than one micrometer, the more so as current semiconductor technologies are apt of producing structures with dimensions in the magnitude of 100 nm or less. With ICs representing a set of electronic circuit elements integrated on a semiconductor material, normally silicon, ICs can be made much smaller than any discreet circuit composed of independent circuit components. Indeed, the majority of present-day ICs are implemented by using a plurality of circuit elements, such as field effect transistors (FETs), also called metal oxide semiconductor field effect transistors (MOSFETs or simply MOS transistors), and passive elements, such as resistors and capacitors, integrated on a semiconductor substrate with a given surface area, wherein typical present-day ICs involve millions of single circuit elements formed on a semiconductor substrate.

The basic function of a FET is that of an electronic switching element, wherein a current through a channel region formed between two junction regions, referred to as source and drain, is controlled by a gate electrode, which is disposed over the channel region and to which a voltage relative to source and drain is applied. In common FETs, the channel region extends along a plane between the source and drain regions, such FETs also being referred to as “planar FETs.” Generally, in applying a voltage exceeding a characteristic voltage level to the gate electrode, the conductivity state of the channel is changed and switching between a conducting state or “ON state” and a non-conducting state or “OFF state” may be achieved. It is important to note that the characteristic voltage level at which the conductivity state changes (usually called “the threshold voltage”), therefore, characterizes the switching behavior of the FET. In fact, it is an ongoing issue in present semiconductor fabrication to keep variations in the threshold value level low for implementing a well-defined switching characteristic. However, as the threshold voltage depends nontrivially on the transistor's properties, e.g., materials, dimensions, etc., the implementation of a desired threshold voltage value during fabrication processes involves careful adjustment and fine-tuning during the fabrication process, which makes the fabrication of advanced semiconductor devices increasingly complex.

The continued miniaturization of semiconductor devices in the deep sub-micron regime becomes more and more challenging with smaller dimensions. One of the several manufacturing strategies employed herein is the implementation of SOI technologies. SOI (silicon-on-insulator) refers to the use of a layered silicon-insulator-silicon substrate in place of conventional silicon substrates in semiconductor manufacturing, especially micro-electronics, to reduce parasitic device capacitance and short channel effects, thereby improving performance. Semiconductor devices on the basis of SOI differ from conventional semiconductor devices formed on a bulk substrate in that the silicon junction is formed above an electrical insulator, typically silicon dioxide or sapphire (these types of devices are called silicon-on-sapphire or SOS devices). The choice of insulator depends largely on the intended application, with sapphire usually being employed in high performance radio frequency applications and radiation-sensitive applications, and silicon dioxide providing diminished short channel effects in microelectronic devices.

In general, a conventional SOI-based semiconductor device comprises a semiconductor layer, e.g., based on silicon and/or germanium, being formed on an insulating layer, e.g., silicon dioxide, which is a so-called buried oxide (BOX) layer formed on a semiconductor substrate. From a physical point of view, the very thin semiconductor film over the BOX layer enables the semiconductor material under the transistor gate, i.e., in the channel region of the semiconductor device, to be fully depleted of charges. The net effect is that the gate can now very tightly control the full volume of the transistor body. Accordingly, an SOI device is better behaved than a bulk device, especially because the supply voltage, i.e., the gate voltage, gets lower and device dimensions are allowed to be scaled.

Basically, there are two types of SOI devices: PDSOI (partially depleted SOI) and FDSOI (fully depleted SOI) devices. For example, in an N-type PDSOI device, a P-type film is sandwiched between a gate oxide (GOX) layer and the buried oxide (BOX) layer which is to be large, such that the depletion region does not cover the whole channel region. Therefore, PDSOI devices behave to some extent like bulk semiconductor devices.

A major problem, particularly in PDSOI, is the so-called “floating body effect” (FBE), which appears because the semiconductor film over the BOX layer is not connected to any of the supplies.

In FDSOI devices, the semiconductor film between the GOX layer and the BOX layer is very thin, such that the depletion region substantially covers the whole semiconductor film. Herein, the GOX layer supports less depletion charges than in bulk applications, and, accordingly, an increase in inversion charges is caused, resulting in higher switching speeds. Additionally, FDSOI devices do in general not require any doping of the channel region. In FDSOI devices, drawbacks of bulk semiconductor devices, like threshold voltage roll off, higher sub-threshold slop body effect, short channel effect, etc., are reduced. The reason is that source and drain electric fields cannot interfere due to the BOX layer bordering the very thin semiconductor film along a depth direction of the SOI substrate.

To separate device regions, shallow trench isolation (STI) structures are formed. An STI structure is generally formed by etching a trench in the SOI structure, filling the trench with a high aspect ratio process (HARP) oxide, and performing a high temperature anneal process to densify the HARP oxide. Forming such STI structures causes degradation in the SOI structure due to the high temperature annealing process. During the annealing, part of the silicon of the active region is consumed, thereby increasing the thickness of the buried oxide (BOX) layer. This reduces the thickness of the active region layer and also tends to relax the material of the active region layer, reducing strain.

The present disclosure is directed to various methods and resulting devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to various methods of forming FDSOI semiconductor devices. One illustrative method includes, among other things, forming a trench in a stack comprising a substrate, a buried oxide layer formed above the substrate, a semiconductor layer formed above the buried oxide layer and a hard mask layer formed above the semiconductor layer. A first liner is formed in the trench. A first oxide layer is formed in the trench. A diffusionless anneal process is performed to densify the first oxide layer. The first oxide layer is recessed to define a recess. A second oxide layer is formed in the recess.

Another method disclosed herein includes, among other things, forming a trench in a stack comprising a substrate, a buried oxide layer formed above the substrate, a semiconductor layer formed above the buried oxide layer and a hard mask layer formed above the semiconductor layer. A silicon nitride liner is formed in the trench. A gap fill oxide layer is formed in the trench. A diffusionless anneal process is performed to densify the gap fill oxide layer. The gap fill oxide layer is recessed to define a recess. A high density process (HDP) oxide layer is formed in the recess.

Yet another method disclosed herein includes, among other things, forming a trench in a stack comprising a substrate, a buried oxide layer formed above the substrate, a semiconductor layer formed above the buried oxide layer and a hard mask layer formed above the semiconductor layer. A silicon nitride liner is formed in the trench. A first oxide layer is formed in the trench. A diffusionless anneal process is performed to densify the first oxide layer. The first oxide layer is recessed to define a recess. A nitride treatment is performed to form a nitridized portion in the first oxide layer. A second oxide layer is formed in the recess.

### BRIEF DESCRIPTION OF THE DRAWINGS

The disclosure may be understood by reference to the following description taken in conjunction with the accompanying drawings, in which like reference numerals identify like elements, and in which:

FIGS. 1A-1H depict various methods disclosed herein of forming an STI structure in an FDSOI device.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure generally relates to various methods of forming a shallow trench isolation (STI) structure in an SOI device without degrading strain in an active region layer of the device. As will be readily apparent to those skilled in the art upon a complete reading of the present application, the present method is applicable to a variety of devices, including, but not limited to, logic devices, memory devices, etc. With reference to the attached figures, various illustrative embodiments of the methods and devices disclosed herein will now be described in more detail.

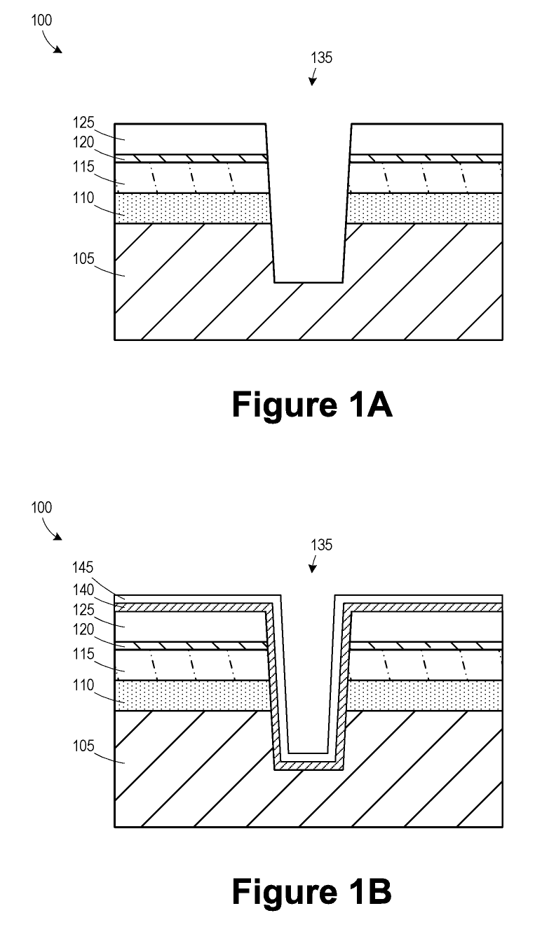

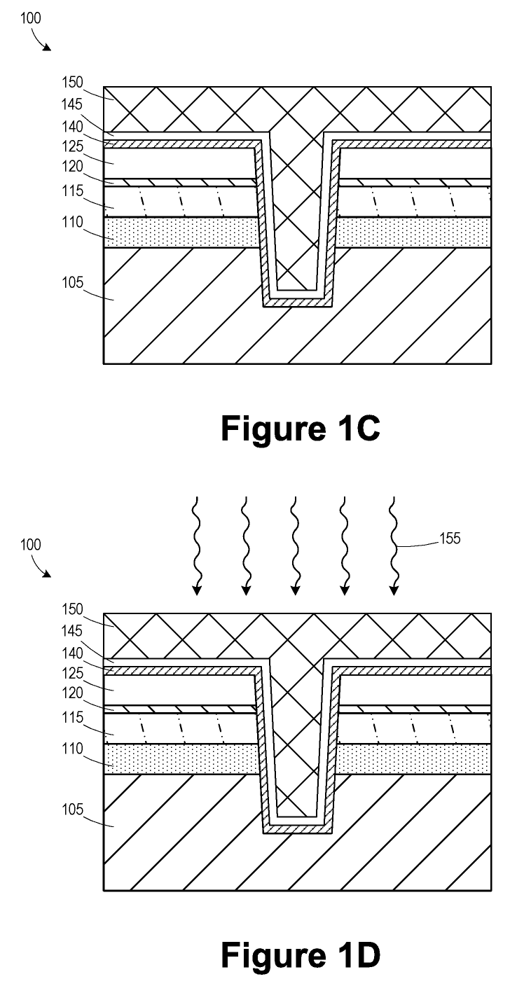

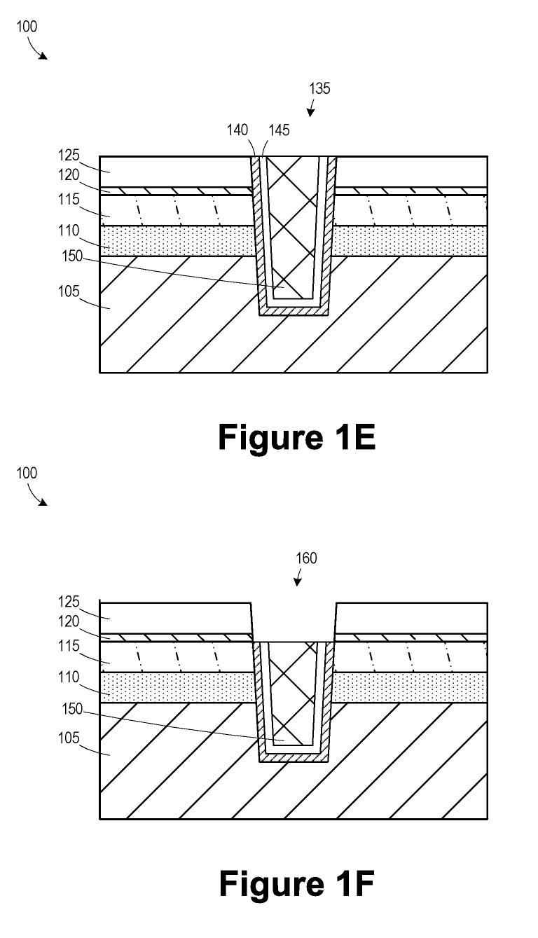

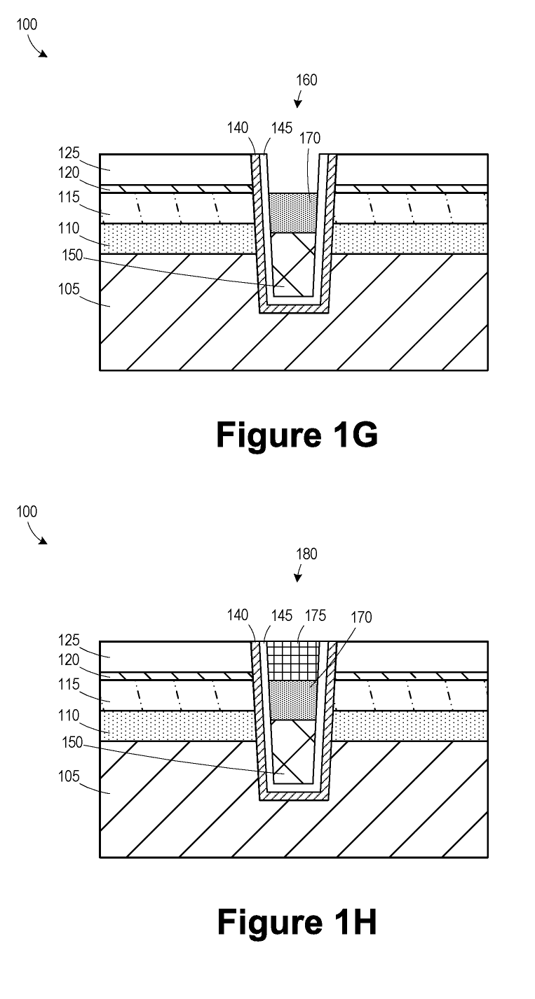

FIGS. 1A-1H depict various methods disclosed herein of forming a shallow trench isolation (STI) structure in an SOI device 100. The SOI device 100 includes a substrate 105, a buried oxide (BOX) layer 110 and a semiconductor layer 115 (e.g., silicon germanium) which is disposed on the BOX layer 110. The substrate 105 may be formed of silicon or silicon germanium or it may be made of materials other than silicon, such as germanium. Thus, the terms “substrate” or “semiconductor substrate” should be understood to cover all semiconducting materials and all forms of such materials. In some embodiments, the semiconductor layer 115 may be silicon germanium, and it may be formed in a strained state. The semiconductor layer 115 defines an active region layer in the device in and above which devices, such as transistors may be formed. A pad oxide layer 120 was formed above the semiconductor layer 115 and a pad nitride layer 125 was formed above the pad oxide layer 120. A patterning process was performed using the pad oxide layer 120 and the pad nitride layer 125 as a hard mask to define a trench 135 in the device 100 extending through the semiconductor layer 115 and the BOX layer 110 and into the substrate 105.

FIG. 1B illustrates the device 100 after a plurality of deposition processes were performed to form a first liner 140 (e.g., silicon nitride) in the trench 135 and a second liner 145 (e.g., silicon dioxide) above the first liner 140. Other liner configurations may be provided such as by providing additional layers (e.g., oxide/nitride/oxide).

FIG. 1C illustrates the device 100 after a deposition process was performed to form a gap fill oxide layer 150 in and above the trench 135. In general, the gap fill oxide layer 150 is formed using a process suitable for high aspect ratio openings. Examples of gap fill oxide processes include a high aspect ratio process (HARP) using a tetraethyl orthosilicate (TEOS) and ozone (O₃) reaction, a flowable chemical vapor deposition (FCVD) process using trisillylamine (TSA) and NH3 with O₃ and/or a UV cure, or a spin-on glass (SOG) process with a bake process.

FIG. 1D illustrates the device 100 after a diffusionless anneal process 155 was performed to anneal the gap fill oxide layer 150. In general, the diffusionless anneal process is a low thermal budget anneal that prevents further oxidation of silicon from the surrounding silicon/oxide interface by minimizing diffusion of any oxidizing species into the interface. This diffusion may be inhibited by either keeping the annealing time shorter than the diffusion time, typically in sub-seconds, or by keeping the annealing temperature lower than a critical temperature of typically 500° C. Examples of diffusionless anneal processes may include an ultrashort laser anneal, a fast ramp spike anneal, or a low temperature oven anneal. A diffusionless anneal can be performed by irradiation with one or more lasers with a pulse duration of ˜20 nanoseconds to 200 nanoseconds. A laser wavelength in a near UV to visible range (e.g., 532 nm and 308 nm), with an energy density of ˜0.5 J/cm2 to about 2.5 J/cm2, may be employed to inhibit oxidation of the BOX layer 110. A low temperature oven anneal process can be performed in the presence of an oxidizing species (e.g., H₂O₂) at or below 500° C. for 30 to 120 mins. In general, the diffusionless anneal process 155 causes reflow of the gap fill oxide layer 150 to fill any voids and to harden the material without causing further oxidation of the BOX layer 110 and resulting consumption of the semiconductor layer 115 or relaxation of strain in the semiconductor layer 115. The second liner layer 145 serves to prevent or reduce oxide diffusion from the gap fill oxide layer 150 into the other layers on the sides of the trench 135.

FIG. 1E illustrates the device 100 after a planarization process was performed to remove portions of the gap fill oxide layer 150 and the liners 140, 145 disposed outside the trench 135 and above the pad nitride layer 125.

FIG. 1F illustrates the device 100 after an etch process was performed to recess the gap fill oxide layer 150 to define a cavity 160. In some embodiments, the etch process may be performed using a Frontier tool from Applied Materials, Inc. In some embodiments, a Frontier etch removes both nitride and oxide, so the portions of the liners 140, 145 disposed on sidewalls of the trench 135 are removed during the recessing etch. In other embodiments, additional wet or dry etch processes may be employed to strip the portions of the liners 140, 145 after the etching of the gap fill oxide layer 150. The etch process is controlled so that the gap fill oxide layer 150 is recessed to about the level of the top surface of the semiconductor layer 115.

FIG. 1G illustrates the device 100 after an optional nitride treatment was performed to define a nitridized portion 170 in the gap fill oxide layer 150. In one embodiment, the nitride treatment includes a plasma treatment using NH₃ or another nitrogen-containing precursor. The depth of the nitridized portion 170 may vary. The nitridized portion 170 exhibits a higher wet etch resistance as compared to the untreated portion of the gap fill oxide layer 150.

FIG. 1H illustrates the device after a plurality of processes was performed. A deposition process was performed to form a high-density process (HDP) oxide cap layer 175 in the cavity 160 (e.g., Plasma power->1 kW, SiH4 flow: 10-200 sccm, and O2 flow: 10-200 sccm) and a planarization process was performed to remove portions of the HDP oxide cap layer 175 disposed above the pad nitride layer 125 and outside the cavity 160, thereby defining an STI structure 180. The HDP oxide layer 175 exhibits a wet etch resistance similar to that which would have been achieved had the gap fill oxide layer 150 been treated with a high temperature anneal (e.g., a furnace anneal).

The use of a diffusionless anneal process for densifying the gap fill oxide layer 150 reduces the likelihood of voids in the material without reducing strain in the semiconductor layer 115 or growth of the BOX layer 110. The nitride treatment and the HDP oxide cap layer 175 improve the wet etch resistance of the STI structure 180.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is, therefore, evident that the particular embodiments disclosed above may be altered or modified and all such variations are considered within the scope and spirit of the invention. Accordingly, the protection sought herein is as set forth in the claims below.

1. A method, comprising:
forming a trench in a stack comprising a substrate, a buried oxide layer formed above said substrate, a semiconductor layer formed above said buried oxide layer and a hard mask layer formed above said semiconductor layer;
forming a first liner in said trench;
after forming said first liner, forming a second liner in said trench contacting said first liner, wherein said first liner comprises silicon nitride and said second liner comprises silicon dioxide;
after forming said second liner, forming a first oxide layer in said trench contacting said second liner;
performing a diffusionless anneal process to densify said first oxide layer;
recessing said first oxide layer to define a recess after performing said diffusionless anneal; and
forming a second oxide layer in said recess.

2. The method of claim 1, wherein said first liner comprises silicon nitride.

3. The method of claim 1, wherein said first oxide layer comprises a high aspect ratio process oxide layer and said second oxide layer comprises a high density process oxide layer.

4. The method of claim 1, further comprising performing a nitride treatment to form a nitridized portion in said first oxide layer after recessing said first oxide layer and prior to forming said second oxide layer.

5. The method of claim 4, wherein said nitride treatment comprises a plasma treatment.

6-7. (canceled)

8. The method of claim 1, wherein said hard mask layer comprises a pad oxide layer formed above said semiconductor layer and a pad nitride layer formed above said pad oxide layer.

9. The method of claim 1, wherein said semiconductor layer comprises strained silicon germanium.

10. A method, comprising:
forming a trench in a stack comprising a substrate, a buried oxide layer formed above said substrate, a semiconductor layer formed above said buried oxide layer and a hard mask layer formed above said semiconductor layer;
forming a silicon nitride liner in said trench;
after forming said silicon nitride liner, forming a silicon dioxide liner in said trench contacting said silicon nitride liner;
after forming said silicon dioxide liner, forming a gap fill oxide layer in said trench contacting said silicon dioxide trench liner;
performing a diffusionless anneal process to densify said gap fill oxide layer;
recessing said gap fill oxide layer to define a recess after performing said diffusionless anneal; and
forming a high density process (HDP) oxide layer in said recess.

11. The method of claim 10, further comprising performing a nitride treatment to form a nitridized portion in said gap fill oxide layer after recessing said gap fill oxide layer and prior to forming said HDP oxide layer.

12. The method of claim 11, wherein said nitride treatment comprises a nitrogen plasma treatment.

13. (canceled)

14. The method of claim 10, wherein said hard mask layer comprises a pad oxide layer formed above said semiconductor layer and a pad nitride layer formed above said pad oxide layer.

15. The method of claim 10, wherein said semiconductor layer comprises strained silicon germanium.

16. A method, comprising:
forming a trench in a stack comprising a substrate, a buried oxide layer formed above said substrate, a semiconductor layer formed above said buried oxide layer and a hard mask layer formed above said semiconductor layer;
forming a silicon nitride liner in said trench;
after forming said silicon nitride liner, forming a silicon dioxide liner in said trench contacting said silicon nitride liner;
after forming said silicon dioxide liner, forming a first oxide layer in said trench contacting said silicon dioxide liner;
performing a diffusionless anneal process to densify said first oxide layer;
recessing said first oxide layer to define a recess after performing said diffusionless anneal;
performing a nitride treatment to form a nitridized portion in said first oxide layer; and
forming a second oxide layer in said recess.

17. The method of claim 16, wherein said first oxide layer comprises a high aspect ratio process oxide layer and said second oxide layer comprises a high density process oxide layer.

18. The method of claim 16, wherein said nitride treatment comprises a nitrogen plasma treatment.

19. (canceled)

20. The method of claim 16, wherein said hard mask layer comprises a pad oxide layer formed above said semiconductor layer and a pad nitride layer formed above said pad oxide layer.
